(19) United States
(12) Patent Application Publication
(10) Pub. No.: US 2017/0179084 A1
(43) Pub. Date: Jun. 22, 2017

(54) LIGHT EMITTING DIODE MODULE

(71) Applicant: LUMENS CO., LTD., Yongin-si (KR)

(72) Inventors: Dae-Won KIM, YONGIN-SI (KR); Min-Pyo KIM, YONGIN-SI (KR); Yong-Wook CHO, YONGIN-SI (KR); Young-Hwan SHIN, YONGIN-SI (KR); Jung-Hye PARK, YONGIN-SI (KR); Sung-Jong PARK, YONGIN-SI (KR)

(73) Assignee: LUMENS CO., LTD., Yongin-si (KR)

(21) Appl. No.: 15/168,023

(22) Filed: May 28, 2016

(30) Foreign Application Priority Data
Dec. 21, 2015 (KR) 10-2015-0182631
Feb. 5, 2016 (KR) 10-2016-0014762

(51) Int. Cl. H01L 25/075; H01L 33/54; H01L 33/48; H01L 33/56; H01L 33/58; H01L 33/60; H01L 33/50

(52) U.S. Cl. CPC H01L 25/0753; H01L 33/60; H01L 33/54; H01L 33/507; H01L 33/56; H01L 33/58; H01L 33/483

(57) ABSTRACT

A light emitting diode module includes: a substrate; LED chips mounted on an upper surface of the substrate; a multi-layer reflector formed on the upper surface of the substrate so as to form a cavity in the vicinity of the LED chips and having an annular shape; and an encapsulant formed of a resin filled in the cavity and containing phosphors, wherein the multi-layer reflector includes a plurality of resin layers having different inner diameters.

### RELATED APPLICATIONS

This application is based on and claims priority to Korean Patent Applications No. 10-2015-0182631, filed on Dec. 21, 2015, and No. 10-2016-0014762, filed on Feb. 5, 2016, which are herein incorporated by reference in their entireties.

### BACKGROUND

Field

The present invention relates to a chip-on-board (COB) type light emitting diode module using a reflector formed by dispensing a resin for the reflector in a multi-layer.

Description of the Related Art

Generally, a chip-on-board (COB) type light emitting diode module includes a substrate, a plurality of LED chips mounted on the substrate, and an encapsulant encapsulating the LED chips. In addition, the encapsulant generally contains phosphors for converting a wavelength of light emitted from the LED chips. A general light emitting diode module generates white light by mixing the light of which the wavelength is converted by the phosphors and light of which a wavelength is not converted with each other.

In the COB type light emitting diode module as described above, in order to form the encapsulant, particularly, the encapsulant containing the phosphors, a silicon resin is applied in a ring shape enclosing the surrounding of the LED chips to form a single-layer reflector, and a liquid-phase or gel-type resin, particularly, a resin containing the phosphors is filled inside the reflector and is then hardened. Here, the reflector performs an important role of allowing the liquid-phase or gel-type resin, more specifically, the resin containing the phosphors not to flow out of a light emitting area.

However, the reflector does not serve to adjust a light distribution angle, particularly, to adjust the light distribution angle to be narrow. For example, an injection-molded reflector may be additionally disposed and be used to adjust the light distribution angle. However, in this case, since the reflector does not sufficiently participate in reflection of the light, a “hot spot area” may be caused, and economical efficiency is low due to the use of the reflector that is expensive and installation of the reflector. Particularly, it has been difficult for the reflector that has been used in an existing light emitting diode module to implement a narrow light distribution angle. As another alternative, there is also a method of using a lens. However, this method also has a problem that economical efficiency is low.

A related patent document is U.S. patent publication 2015/0016107 A1 (2015 Jan. 15).

### SUMMARY

An object of the present invention is to provide a light emitting diode module in which a reflector may be formed by dispensing a resin for the reflector in a multi-layer to serve to adjust a light distribution angle.

According to an aspect of the present invention, a light emitting diode module includes: a substrate; LED chips mounted on an upper surface of the substrate; a multi-layer reflector formed on the upper surface of the substrate so as to form a cavity in the vicinity of the LED chips and having an annular shape; and an encapsulant formed of a resin filled in the cavity and containing phosphors, wherein the multi-layer reflector includes a plurality of resin layers having different inner diameters.

The multi-layer reflector may include a first resin layer for the reflector annularly formed on the substrate and a second resin layer for the reflector stacked on the first resin layer for the reflector.

The multi-layer reflector may include spiral resin layers for the reflector continuously connected to each other in a spiral shape toward the top.

An inner diameter of the multi-layer reflector may be gradually decreased toward the top.

The resin filled in the cavity and containing the phosphors may include a concave light emitting surface.

A height of an upper end of the resin filled in the cavity and containing the phosphors may be generally lower than that of an upper end of the multi-layer reflector. An inner side of a cross section of the cavity may be any one of one straight line, a combination of straight lines, one curved line, a combination of curved lines, and a combination of lines including a straight line and a curved line.

The multi-layer reflector may be formed of a resin material in which a translucent resin including a silicon resin or an epoxy resin and a reflection material selected from the group consisting of TiO₂, SiO₂, ZrO₂, PbCO₃, PbO, Al₂O₃, ZnO, and Sb₂O₃ are mixed with each other.

The encapsulant may have convex shape in a direction that becomes distant from the substrate, a central axis of the encapsulant may coincide with a central axis of the cavity, and the number of LED chips provided in the cavity may be plural.

The multi-layer reflector may have a height higher than the highest height of the plurality of LED chips and lower than the highest height of the encapsulant.

The multi-layer reflector may have the same interval with respect to an array central point of the plurality of LED chips in all directions.

The encapsulant may include: an encapsulating body positioned in an area occupied by the cavity; and an encapsulating branch extended from the encapsulating body so as to cover an upper surface of the multi-layer reflector.

The encapsulating branch may contain a mixture of the phosphors and silicon.

The encapsulating branch may include: an inclination portion inclined downward in a separation direction that becomes distant from the central axis of the cavity; and a flat portion flatly extended from the inclination portion in the separation direction.

The inclination portion may include: a first section having a height decrease rate increased in the separation direction; and a second section extended from the first section and having a height decrease rate converged on zero in the separation direction.

The encapsulant may include: an encapsulating body having a symmetrical shape in relation to the central axis of the cavity; and an encapsulating branch connected to the encapsulating body so as to enclose the encapsulating body and covering the entirety of an upper surface of the multi-layer reflector.

The encapsulating branch may include: an inclination portion inclined downward in a separation direction that becomes distant from the central axis of the cavity; and a flat portion flatly extended from the inclination portion to an outer end portion of the multi-layer reflector.

The inclination portion may include: a first section having a height decrease rate increased in the separation direction; and a second section extended from the first section and having a height decrease rate converged on zero in the separation direction.

### BRIEF DESCRIPTION OF THE DRAWINGS

FIG. 1 is a plan view illustrating a light emitting diode module according to an exemplary embodiment of the present invention.

FIG. 2 is a cross-sectional view of the light emitting diode module taken along line I-I of FIG. 1.

FIG. 3 is a cross-sectional view for describing a light emitting diode module according to another exemplary embodiment of the present invention.

FIGS. 4A and 4B are cross-sectional views for describing other exemplary embodiments of the present invention in which a shape of an inner portion of a cross section of a cavity of the light emitting diode module is changed.

FIG. 5, which is a front view illustrating a light emitting diode module according to still another exemplary embodiment of the present invention, is a view illustrating an LED chip by a hidden line.

FIGS. 6A to 6C are, respectively, a front photograph, a plan photograph of a light emitting diode module using a single-layer reflector in a state in which an encapsulant is omitted, and a diagram of a light distribution angle that is obtained.

FIGS. 7A to 7C are, respectively, a front photograph, a plan photograph of a light emitting diode module using a three-layer reflector in a state in which an encapsulant is omitted, and a diagram of a light distribution angle that is obtained.

FIGS. 8A to 8C are, respectively, a front photograph, a plan photograph of a light emitting diode module using a five-layer reflector in a state in which an encapsulant is omitted, and a diagram of a light distribution angle that is obtained.

FIGS. 9A, 9C, and 9E are front photographs of light emitting diode modules in which single-layer, three-layer, and five-layer reflectors are used and encapsulants containing phosphors are filled in each of these reflectors at a maximum height to be substantially flat.

FIGS. 9B, 9D, and 9F are diagrams of light distribution angles of each of these light emitting diode modules, respectively in FIGS. 9A, 9C, and 9E.

FIGS. 10A, 10C, and 10E are front photographs of light emitting diode modules in which the number of layers of reflectors are the same as each other (that is, reflectors are three-layer reflectors), all the remaining conditions are the same as each other, and only heights of encapsulants containing phosphors are different from each other. FIGS. 10B, 10D, and 10F are diagrams of light distribution angles of each of these light emitting diode modules respectively in FIGS. 10A, 10C, and 10E.

FIG. 11 is a perspective view illustrating a light emitting device package 100 according to an exemplary embodiment of the present invention.

FIG. 12 is a cross-sectional view of the light emitting device package 100 taken along line II-II of FIG. 11.

FIG. 13 is an enlarged cross-sectional view illustrating configurations of a reflector 150 and an encapsulant 170 of FIG. 12.

FIG. 14 is an enlarged cross-sectional view illustrating configurations of a reflector 250 and an encapsulant 270 of a light emitting device package 200 according to another exemplary embodiment of the present invention.

FIG. 15 is an enlarged cross-sectional view illustrating configurations of a reflector 350 and an encapsulant 370 of a light emitting device package 300 according to still another exemplary embodiment of the present invention.

### DETAILED DESCRIPTION

Hereinafter, exemplary embodiments of the present invention will be described with reference to the accompanying drawings. The accompanying drawings and a description for the accompanying drawings are provided in order to assist in the understanding of the present invention by those skilled in the art. Therefore, it is not to be interpreted that the accompanying drawings and the description limit the scope of the present invention.

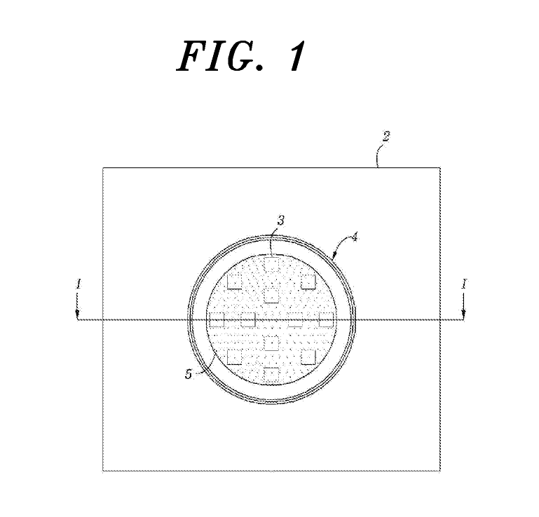

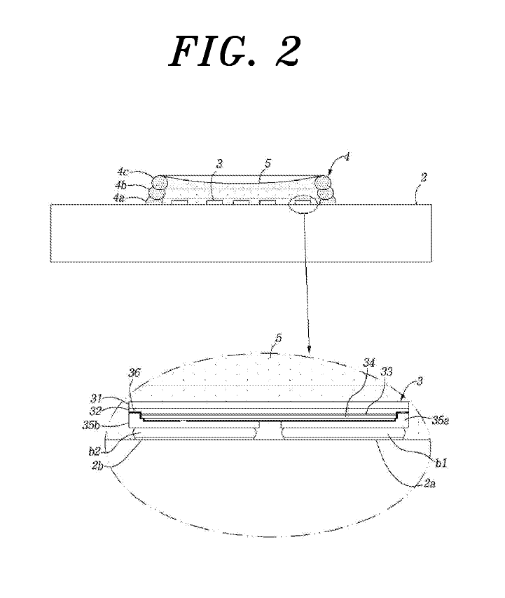

FIG. 1 is a plan view illustrating a light emitting diode module according to an exemplary embodiment of the present invention, and FIG. 2 is a cross-sectional view of the light emitting diode module taken along line I-I of FIG. 1.

Referring to FIGS. 1 and 2, the light emitting diode module according to an exemplary embodiment of the present invention, which may be usefully used in, for example, a surface light source apparatus for illumination, includes a substrate 2, a plurality of LED chips 3 mounted on an upper surface of the substrate 2, a reflector 4 formed on the upper surface of the substrate 2 to define a cavity in the vicinity of the plurality of LED chips 3 and having an annular shape, and an encapsulant 5 formed by hardening a liquid-phase or gel-type resin for encapsulating a chip filled in the cavity.

The encapsulant 5 may contain phosphors converting a wavelength of light emitted from the plurality of LED chips 3. When the resin for encapsulating a chip obtained by mixing the phosphors with the liquid-phase or gel-type resin is filled in the cavity and is then hardened, the encapsulant 5 in which the phosphors are substantially uniformly dispersed may be obtained. For example, light that is emitted from the LED chips 3 and does not pass through the phosphors and light of which a wavelength is converted by the phosphors may be mixed with each other to generate white light.

The plurality of LED chips 3 may be arrayed on the substrate 2 in a state in which they are connected to each other in series or in series and parallel as an example. In addition, the plurality of LED chips 3 may be included in an alternating current (AC) circuit. Preferably, the plurality of LED chips 3 may be flip-chip type LED chips 3 mounted on the substrate 2 without using bonding wires.

The flip-chip type LED chip 3 includes a translucent substrate 31, a first conductive-type semiconductor layer 32, an active layer 33, and a second conductive-type semiconductor layer 34 sequentially disposed from the top toward the bottom, and has a structure in which a partial area of the first conductive-type semiconductor layer 32 opened by mesa etching is connected to a first electrode pad 35a and a partial area of the second conductive-type semiconductor layer 34 is connected to a second electrode pad 35b. An insulating layer 36 is formed to insulate the first electrode pad 35a from the second conductive-type semiconductor layer 34 and the second electrode pad 35b and insulate the second electrode pad 35b from the first conductive-type semiconductor layer 32 and the first electrode pad 35a. The translucent substrate 31 may be a growth substrate used to grow the first conductive-type semiconductor layer 32 formed of a gallium nitride based material, the active layer 33, and the second conductive-type semiconductor layer 34, more preferably, a sapphire substrate. The first conductive-type semiconductor layer 32 and the second conductive-type semiconductor layer 34 may be an n-type semiconductor layer and a p-type semiconductor layer, and the active layer may include a multi-quantum well. When the flip-chip type LED chip 3 is mounted on the substrate 2, the first and second electrode pads 35a and 35b are connected, respectively, to electrodes 2a and 2b on the substrate 2 by solder bumps b1 and b2.

In addition, the reflector 4 is configured to perform a function of a reflector making a light distribution angle narrow after the manufacturing of the light emitting diode module is completed, unlike an existing single-layer reflector that has defined only a space in which the liquid-phase or gel-type resin for encapsulating a chip is filled. To this end, the reflector 4 may be formed by stacking resin layers 4a, 4b, and 4c formed by dispensing a white silicon resin for a reflector in an annular shape in a multi-layer and to have inner diameters that are gradually decreased toward the top. According to the present exemplary embodiment, the reflector 4 sequentially includes a first resin layer 4a, a second resin layer 4b, and a third resin layer 4c having inner diameters that are gradually decreased toward the top to have different inner diameters. Therefore, the reflector 4 may be called a multi-layer reflector.

The first resin layer 4a, which is an annular pattern having a first inner diameter and a first outer diameter with respect to a vertical central line, and is formed by applying a liquid-phase or gel-type white silicon resin onto the substrate 2. To this end, a dispenser dispensing a resin while rotating in a state in which it is spaced apart from the virtual central line by a predetermined radius is used. In addition, the second resin layer 4b may be formed using the same dispenser. The second resin layer 4b, which is an annular pattern having a second outer diameter larger than the first inner diameter and smaller than the first outer diameter and a second inner diameter smaller than the first inner diameter with respect to the vertical central line, and is formed by applying a liquid-phase or gel-type resin onto the substrate 2. In addition, the third resin layer 4c may be formed using the same dispenser. The third resin layer 4c, which is an annular pattern having a third outer diameter larger than the second inner diameter and smaller than the second outer diameter and a third inner diameter smaller than the second inner diameter with respect to the vertical central line, and is formed by applying a liquid-phase or gel-type resin onto the substrate 2.

As the white silicon resin configuring the reflector 4, a mixture of a material selected from the group consisting of TiO₂, SiO₂, ZrO₂, PbCO₃, PbO, Al₂O₃, ZnO, and Sb₂O₃ which are reflection materials, and a silicon resin may be used.

The reflector 4 may be formed by stacking the following another resin layer after the preceding resin layer is hardened or be formed by sequentially stacking resin layers and then hardening the resin layers en bloc. When the reflector 4 is hardened, the resin for encapsulating a chip containing the phosphors is filled in the cavity in the reflector 4 and is then hardened, such that the encapsulant 5 containing the phosphors is formed.

In the present exemplary embodiment, the encapsulant 5 has a concave upper surface, that is, a light emitting surface. A height of an edge of the upper surface of the encapsulant 5 is substantially the same as that of the reflector 4, and a height of the center of the upper surface of the encapsulant 5 is lowest. In the case in which the encapsulant 5 is formed in a concave shape as described above, the phosphors may be used as much as possible, and a light distribution angle adjusting area by the reflector 4 is sufficiently secured at an upper side of the encapsulant 5, thereby making it possible to obtain a desired light distribution angle, that is, a sufficiently narrow light distribution angle. It is preferable that a silicon resin is used as a resin for forming the encapsulant 5.

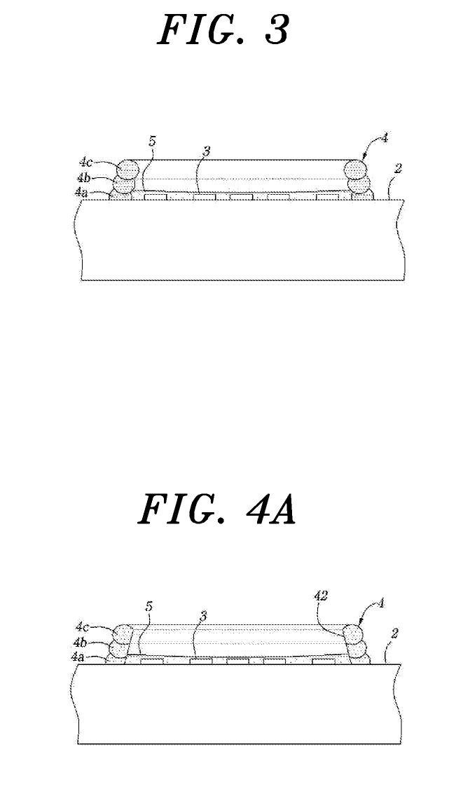

FIG. 3 is a cross-sectional view for describing a light emitting diode module according to another exemplary embodiment of the present invention.

The light emitting diode module according to the present exemplary embodiment includes a reflector 4 formed on an upper surface of the substrate 2 at the same height and layer as those of the above-mentioned exemplary embodiment by the same method as that of the above-mentioned exemplary embodiment. In addition, the light emitting diode module includes a plurality of LED chips 3 mounted on the substrate 2 at the same array as that of the above-mentioned exemplary embodiment. In addition, the light emitting diode module according to the present exemplary embodiment includes an encapsulant 5 encapsulating the plurality of LED chips 3. An entire height of an upper end surface of the encapsulant 5 is positioned to be much lower than a height of an upper end of the reflector 4, more specifically, to be lower than a height of the middle of the reflector 4.

In the present exemplary embodiment, the encapsulant 5 is formed by a resin for encapsulating a chip filled at a height equal to or lower than that of the first resin layer 4a positioned at the lowest position among the first resin layer 4a, the second resin layer 4b, and the third resin layer 4c to cover and protect the LED chips 3 at a position slightly higher than that of upper surfaces of the LED chips 3. In addition, the encapsulant 5 contains phosphors for converting a wavelength of light, similar to the above-mentioned exemplary embodiment. Since an upper end of the encapsulant 5 containing the phosphors is positioned at a height lower than that of the reflector 4, it is possible to adjust a light distribution angle to be narrower using inner side surface reflection of the reflector 4 positioned at a height higher than the upper end surface of the encapsulant 5.

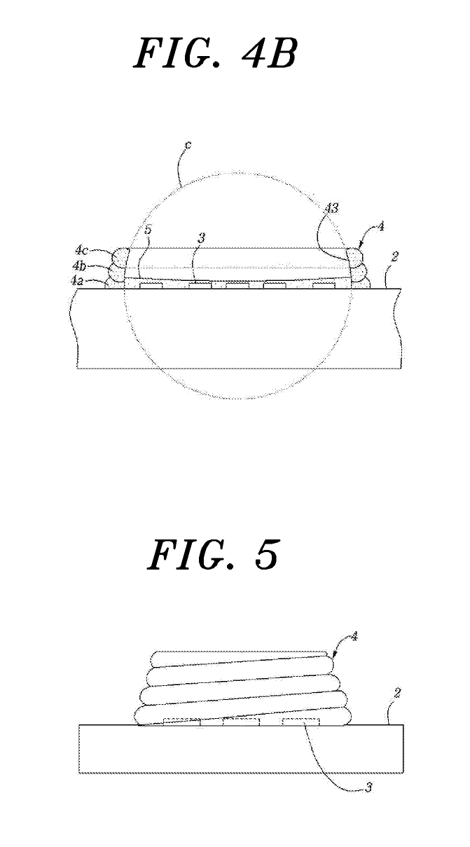

FIGS. 4A and 4B are cross-sectional views for describing other exemplary embodiments of the present invention in which a shape of an inner portion of a cross section of a cavity of the light emitting diode module is changed.

First, referring to FIG. 4A, the reflector 4 of the light emitting diode module is formed by stacking resin layers 4a, 4b, and 4c formed by dispensing a white silicon resin for a reflector in an annular shape in a multi-layer. Here, it may be appreciated that an inner portion of a cross section of a cavity defined by the reflector 4 has a trapezoidal shape and an inner side 42 of the cross section of the cavity is formed of one inclined straight line. When an inner surface of the cavity is smoothly formed so that the inner side 42 of the cross section of the cavity is one straight line, an inner surface of the reflector 4 becomes smooth, which may be advantageous in obtaining light having an intended light distribution angle. In addition, referring to FIG. 4B, it may be appreciated that an inner side 43 of a cross section of a cavity defined by the reflector 4 is one curved line, more specifically, an arc configuring a portion of a virtual circle c denoted by a two-dot chain line. Alternatively, an inner side of a cross section of the cavity may be selected from a combination of several straight lines, a combination of several curved lines, or a combination of lines including a straight line and a curved line.

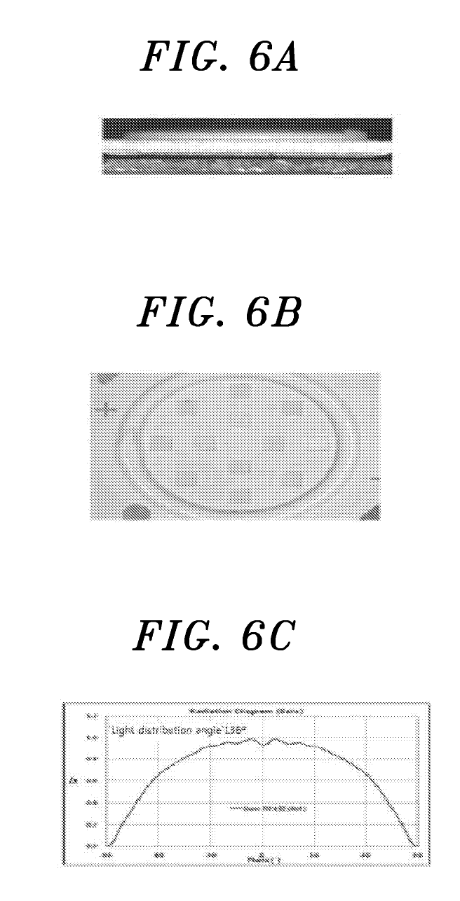

FIG. 5, which is a front view illustrating a light emitting diode module according to still another exemplary embodiment of the present invention, is a view illustrating an LED chip by a hidden line.

Referring to FIG. 5, the light emitting diode module according to the present exemplary embodiment includes a spiral reflector 4 in which resin layers are continuously connected to each other and are formed to become narrow toward the top. According to the present exemplary embodiment, the spiral reflector 4 is formed by spirally dispensing a resin for a reflector to gradually become narrow toward the top. The resin layers for a reflector 4 are continuously connected to each other, such that a plurality of resin layers form a continuous spiral shape. According to the present invention, the light distribution angle may be adjusted by adjusting the number of layers of the resin layers, and it may be more efficient to form the reflector 4 by spirally applying the resin for a reflector as in the present exemplary embodiment.

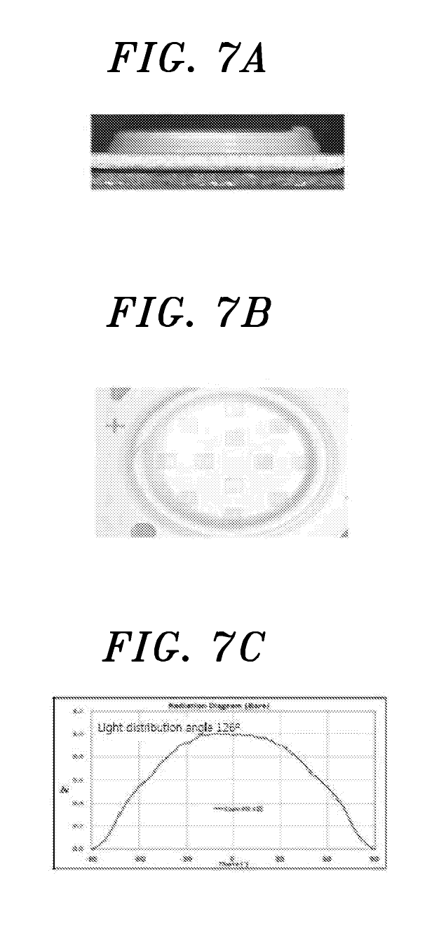

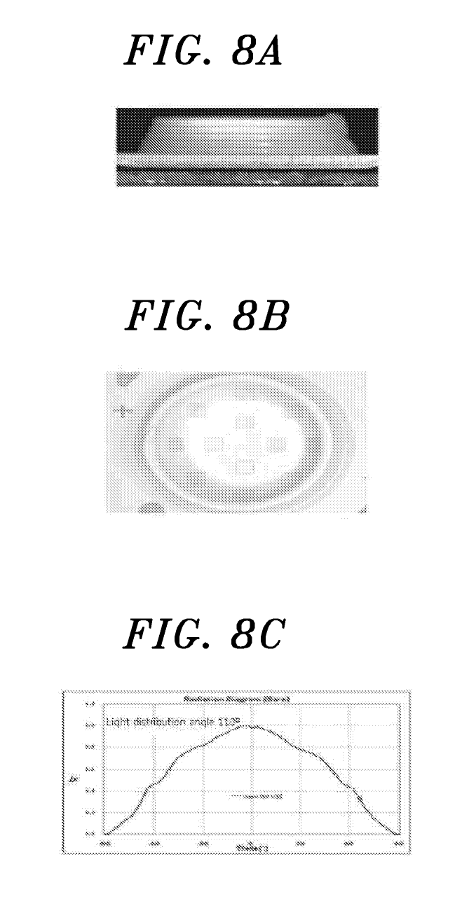

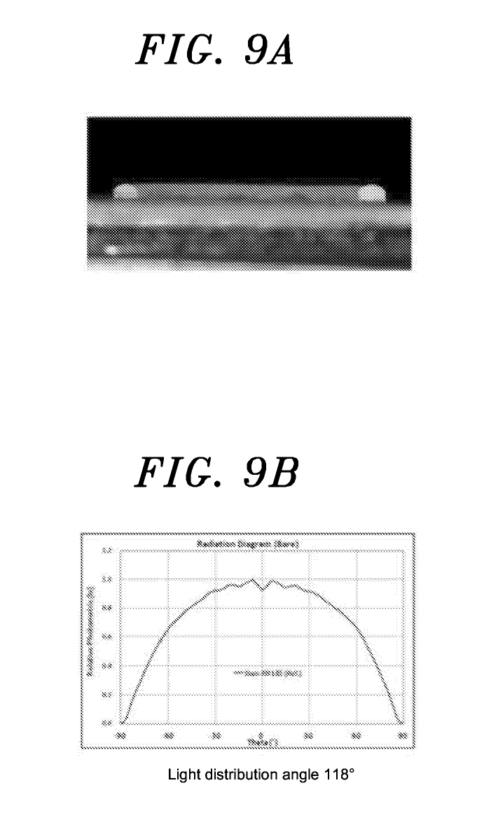

FIGS. 6A to 6C are, respectively, a front photograph and a plan photograph of a light emitting diode module using a single-layer reflector in a state in which an encapsulant is omitted and a diagram of a light distribution angle that is obtained, FIGS. 7A to 7C are, respectively, a front photograph and a plan photograph of a light emitting diode module using a three-layer reflector in a state in which an encapsulant is omitted and a diagram of a light distribution angle that is obtained, and FIGS. 8A to 8C are, respectively, a front photograph and a plan photograph of a light emitting diode module using a five-layer reflector in a state in which an encapsulant is omitted and a diagram of a light distribution angle that is obtained. Referring to FIGS. 6 to 8, it may be appreciated that when the number of layers of the reflector is increased to a single-layer, a three-layer, and a five-layer in a state in which the encapsulant is not present, a light distribution angle of the light emitting diode module is gradually decreased to 136 degrees, 126 degrees, and 110 degrees.

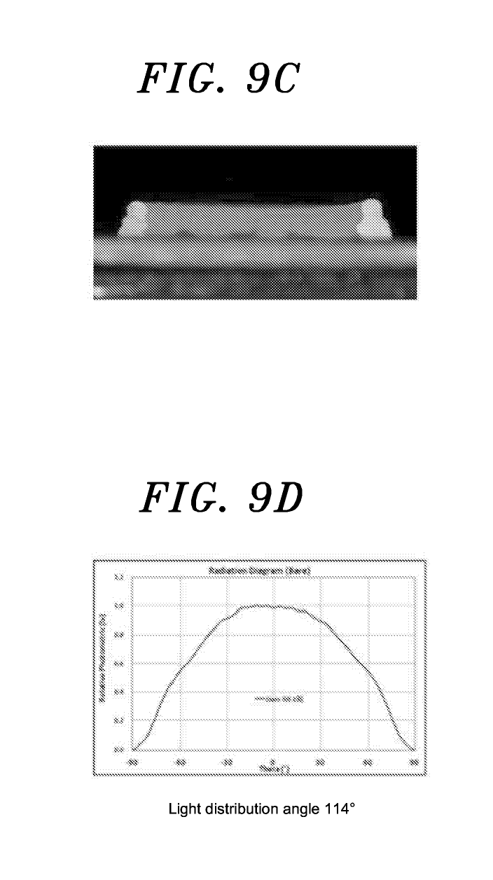

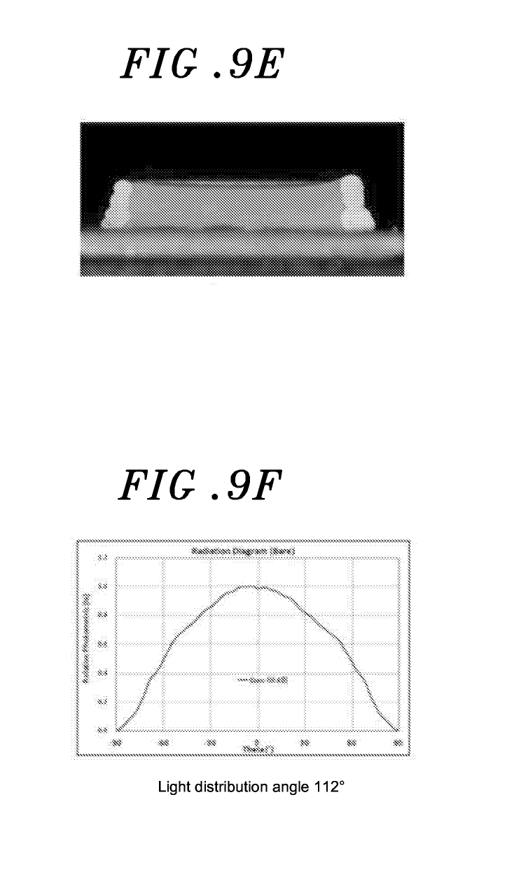

FIGS. 9A, 9C, and 9E are front photographs of light emitting diode modules in which single-layer, three-layer, and five-layer reflectors are used and encapsulants containing phosphors are filled in each of these reflectors at a maximum height to be substantially flat. FIGS. 9B, 9D, and 9F are diagrams of light distribution angles of each of these light emitting diode modules respectively in FIGS. 9A, 9C, and 9E.

Referring to FIGS. 9A to 9E, it may be appreciated that as the number of layers of the reflector and a height depending on the number of layers are increased, a light distribution angle may be adjusted to be narrow, similar to the case in which the encapsulant is not present. In the case of using the single-layer reflector filled with the encapsulant, a light distribution angle of 118 degrees may be obtained, in the case of using the three-layer reflector filled with the encapsulant, a light distribution angle of 114 degrees may be obtained, and in the case of using the five-layer reflector filled with the encapsulant, a light distribution angle of 112 degrees may be obtained.

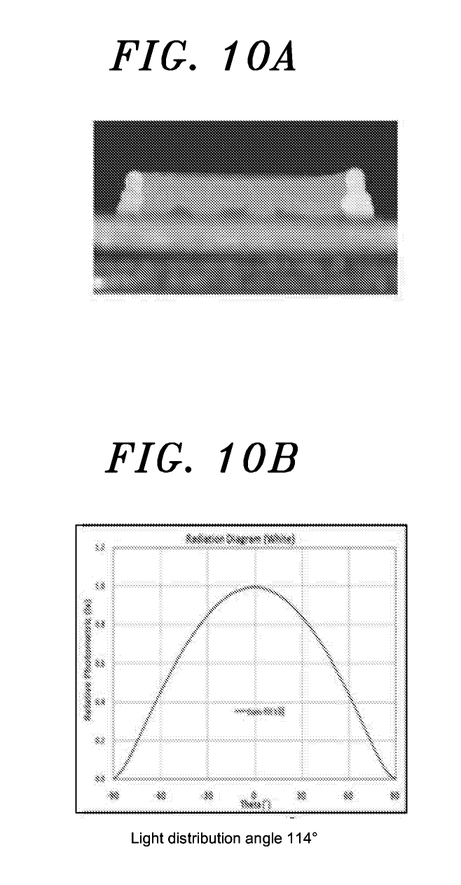

FIGS. 10A, 10C, and 10E are front photographs of light emitting diode modules in which the number of layers of reflectors are the same as each other (that is, reflectors are three-layer reflectors), all the remaining conditions are the same as each other, and only heights of encapsulants containing phosphors are different from each other. FIGS. 10B, 10D, and 10F are diagrams of light distribution angles of each of these light emitting diode modules respectively in FIGS. 10A, 10C, and 10E.

FIGS. 10A and 10B illustrate a case in which the encapsulant is filled at a maximum height to be flat (flat dotting), FIGS. 10C and 10D illustrate a case in which the encapsulant is filled at a maximum height and is concavely filled by slightly decreasing an amount of dotted resin (under dotting), and FIGS. 10E and 10F illustrate a case in which the encapsulant is filled at a minimum height at which it may cover the LED chips (inner dotting). A light distribution angle was smallest (111 degrees) in the case of the inner dotting, was 112 degrees in the case of the under dotting, and was 114 degrees in the case of the flat dotting.

Next, a problem that the LED chips or materials enclosing the LED chips are vulnerable to moisture permeated from the outside thereinto needs to be solved. This problem may be solved by allowing the encapsulant described above to have a special structure.

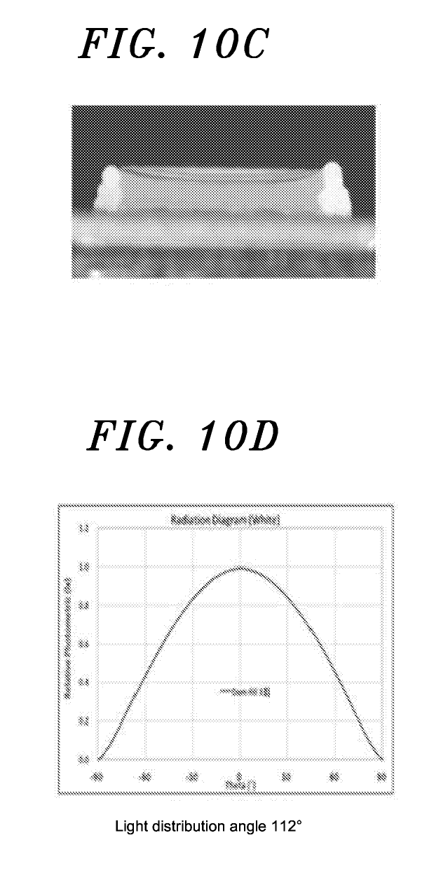

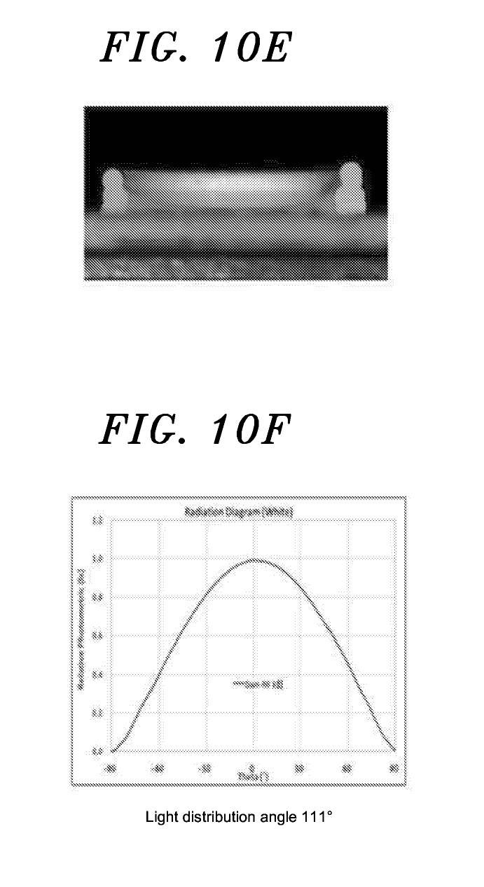

First, FIG. 11 is a perspective view illustrating a light emitting device package 100 according to an exemplary embodiment of the present invention, and FIG. 12 is a cross-sectional view of the light emitting device package 100 taken along line II-II of FIG. 11.

Referring to FIGS. 11 and 12, the light emitting device package 100 may include a substrate 110, LED chips 130, a reflector 150, a cavity 160, and an encapsulant 170.

The substrate 110 is a target on which the LED chips 130 are mounted, and is electrically connected to the LED chips 130. The substrate 110 may have terminals for electrically connecting the LED chips 130 to external connectors.

The LED chip 130 is a component for outputting light. The LED chip 130, which is a flip type optical semiconductor, has a form in which a plurality of light emitting cells is connected to each other in series. In detail, the light emitting device 130 may be completed by mesa-etching the flip type optical semiconductor at a plurality of positions to divide the flip type optical semiconductor into a plurality of cells and then forming electrical conductive paths between the plurality of cells.

The reflector 150 is a component disposed on the substrate 110 to enclose the LED chips 130. Therefore, the reflector 150 may have a closed loop shape, for example, a circular shape. In this case, the reflector 150 may have the same interval with respect to an array center AC of the plurality of LED chips 130 in all directions.

In addition, the reflector 150 may maintain the encapsulant 170 in a state in which the encapsulant 170 covers the LED chips 130, and reflect light generated in the LED chips 130. To this end, the reflector 150 may have a height higher than the highest height of the plurality of LED chips 130 and lower than the highest height HP of the encapsulant 170.

The reflector 150 may be formed of at least one of a silicon polymer, an epoxy resin composition, a silicon resin composition, a modified epoxy resin composition, a modified silicon resin composition, and a polyimide resin composition in terms of a material.

The cavity 160 is an empty space defined by the substrate 110 and the reflector 150. Referring to FIG. 12, the cavity 160 may be a substantially cylindrical space. A central axis CC of the cavity 160 may pass through the array center AC.

The encapsulant 170 is formed by a molding material covering the LED chips 130 and the cavity 160, and is a component protecting the LED chips 130 and passing light generated in the LED chips 130 therethrough. The molding material may contain silicon and a wavelength converting material. The wavelength converting material may be any one of a green phosphor, a red phosphor, and a yellow phosphor, or a mixture thereof.

The encapsulant 170 may have a central axis MC coinciding with the central axis CC of the cavity 160. A central axis CC of the encapsulant 170 may also pass through the array center AC. Here, the encapsulant 170 may have a symmetrical shape in relation to the central axis MC.

In detail, the encapsulant 170 may include an encapsulating body 171 and an encapsulating branch 175.

The encapsulating body 171 is filled in an area occupied by the cavity 160 in the present exemplary embodiment. The encapsulating body 171 may have a convex shape in a direction D that becomes distant from the substrate 110. Here, the encapsulating body 171 may have a cup cake shape.

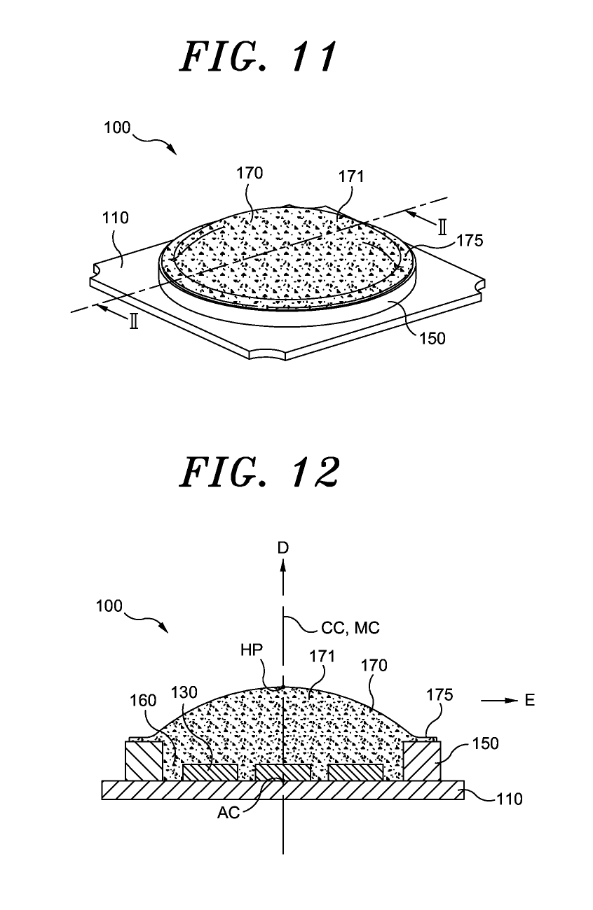

The encapsulating branch 175 is connected to the encapsulating body 171, and is positioned on an upper surface 155 (see FIG. 13) of the reflector 150. The encapsulating branch 175 is to prevent moisture from permeating into a central portion of the encapsulating body 171 and into the LED chips 130 through an edge of the encapsulating body 171.

The encapsulating branch 175 may be molded integrally with the encapsulating body 171. In this case, a boundary line for dividing the encapsulating branch 175 and the encapsulating body 171 from each other is not formed between the encapsulating branch 175 and the encapsulating body 171. In FIGS. 11 and 12, a form in which the encapsulating branch 175 and the encapsulating body 171 are formed integrally with each other is illustrated.

Again referring to FIGS. 11 and 12, the encapsulating branch 175 may have a closed loop shape continuously formed along an outer diameter edge of the encapsulating body 171, for example, a ring shape. The encapsulating branch 175 described above prevents permeation of moisture in any direction along the outer diameter edge of the encapsulating body 171.

The encapsulating branch 175 may be formed to be substantially lower than the encapsulating body 171. In detail, a maximum height of the encapsulating branch 175 may be one of several to one of several tens or less of a maximum height of the encapsulating body 171.

Next, detailed configurations of the encapsulating body 171 and the encapsulating branch 175 will be described in connection with the reflector 150 with reference to FIG. 3. FIG. 13 is an enlarged cross-sectional view illustrating configurations of the reflector 150, the encapsulating body 171, and the encapsulating branch 175 of FIG. 12.

Referring to FIG. 13, first, the reflector 150 has a substantially rectangular shape. The reflector 150 may have an inner edge 151, an outer edge 153, the upper surface 155, and an exposure area 157.

The inner edge 151 may be an edge close to the center of the encapsulant 170, of two edges 151 and 153. The outer edge 153 faces the inner edge 151. The upper surface 155 may be substantially flat. The exposure area 157 is a portion of the upper surface 155 that is not covered by the encapsulating branch 175, but is exposed to the outside.

A boundary line B conceptually dividing the encapsulating body 171 and the encapsulating branch 175 from each other corresponds to the inner edge 151 of the reflector 150. Therefore, the encapsulating branch 175 is attached onto the upper surface 155 of the reflector 150 in an entire area of the encapsulating branch 175.

The encapsulating branch 175 divided as described above will be described in detail. First, the encapsulating branch 175 may have an inclination portion 176. The inclination portion 176 is a portion of the encapsulating branch 175 having an inclination shaped contour. In detail, the inclination portion 176 may have a form in which it is inclined downward in a separation direction E that becomes distant from the central axis CC (see FIG. 12) of the cavity 160.

The inclination portion 176 may be divided into a first section 176a and a second section 176b. The first section 176a is a section in which a decrease rate of a height is increased in the separation direction E, and the second section 176b is a section in which a decrease rate of a height is decreased. The second section 176b may also be a section in which a decrease rate of a height is decreased to be finally converged on zero.

The encapsulating branch 175 may further have a flat portion 178 flatly extended from the inclination portion 176 in the separation direction E. The flat portion 178 is connected from the lowest point 176′ of the inclination portion 176. Therefore, the flat portion 178 may have a fine inclination at a portion thereof close to the lowest point 176′, but may be defined to have a generally flat shape.

Hereinafter, the principle that the possibility that moisture will permeate into the encapsulant 170, more specifically, the encapsulating body 171 is decreased by the configuration described above will be described.

First, since the encapsulating branch 175 has the inclination portion 176, a moisture particle positioned at the encapsulating branch 175 (at a point \textcircled{a}) is rolled down toward the lowest point 176′ by gravity. Here, the moisture particle moved to the lowest point 176′ (at a point \textcircled{b}) is rolled without being stopped by force accumulated while being rolled in the first section 176a [and the second section 176b]. Then, the moisture particle may pass through the flat portion 178 and then drop to the outside of the exposure area 157 or the reflector 150. Therefore, an amount of moisture particle positioned at an end portion (a point \textcircled{c}) of the flat portion 178 to permeate into the encapsulating branch 175 may be minimized.

Next, when the flat portion 178 has a height equal to or lower than a height of the lowest point 176′, the height itself of the flat portion 178 is a low height. Therefore, a size itself of the moisture particle present at the point \textcircled{c} is decreased as compared with the case in which the encapsulating branch 175 directly contacts the reflector 150 while maintaining a profile of the first section 176a without the flat portion 178.

As a result, force by which the moisture particle present at the point \textcircled{c} and having a small size lifts the encapsulating branch 175 is relatively weak. Even though the moisture particle present at the point \textcircled{c} finely lifts the encapsulating branch 175, more specifically, the flat portion 178, only the flat portion 178 is slightly bent on the basis of the point \textcircled{b}.

As a result, the moisture particle does not integrally lift the encapsulating branch 175 and the encapsulating body 171, and should again lift the inclination portion 176 of the encapsulating branch 175 at a point \textcircled{d}. Here, even though a moisture particle present at the point \textcircled{d} is expanded/contracted by turn on/off of the LED chips 130 (see FIG. 12), the moisture particle is covered by the flat portion 178 of the encapsulating branch 175, such that it restrictively contacts external air. Therefore, a temperature change in the moisture particle present at the point \textcircled{d} is not large, such that force by which the moisture particle lifts the inclination portion 176 of the encapsulating branch 175 by expansion/contraction is not largely exerted.

Further, a permeation path through which the moisture particle permeates into the encapsulating body 171 becomes long due to the existence of the encapsulating branch 175, such that it is difficult for the moisture particle to permeate into the center of the encapsulant 170.

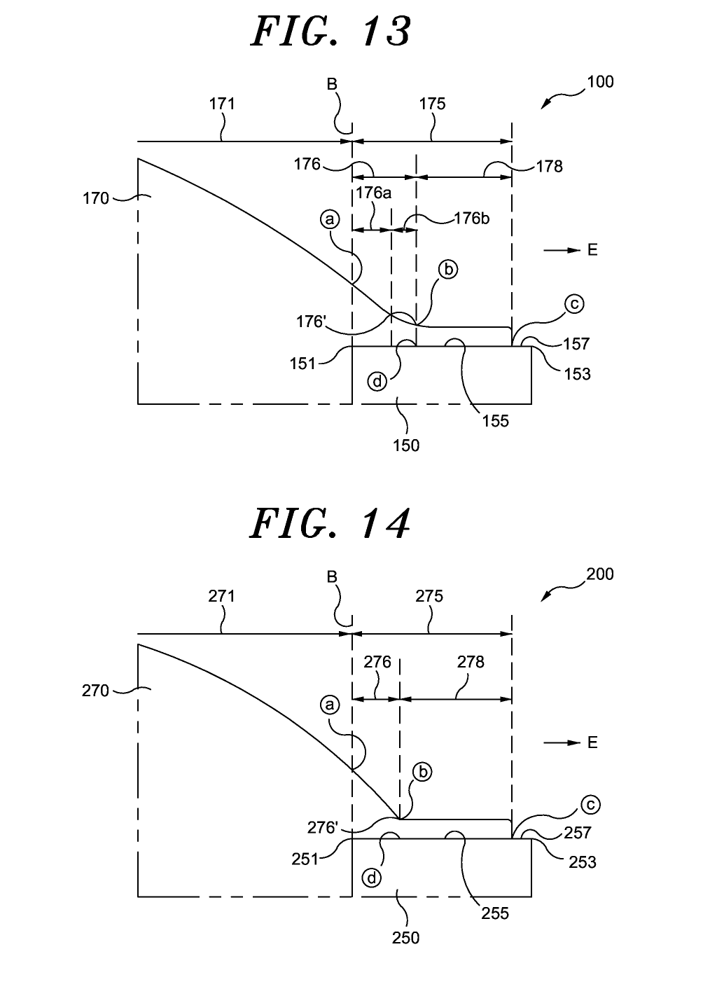

Next, a light emitting device package 200 having another form will be described with reference to FIG. 14.

FIG. 14 is an enlarged cross-sectional view illustrating configurations of a reflector 250 and an encapsulant 270 of a light emitting device package 200 according to another exemplary embodiment of the present invention.

Referring to FIG. 14, a reflector 250 and an encapsulant 270 of the light emitting device package 200 are substantially similar to the reflector 150 and the encapsulant 170 of the above-mentioned exemplary embodiment. However, an inclination portion 276 of an encapsulating branch 275 is different from the inclination portion 176 of the encapsulating branch 175 described above.

In detail, the inclination portion 276 of the encapsulating branch 275 has a form in which a decrease rate of a height is increased over an entire section. This allows a contour of the inclination portion 276 to have a form configuring a portion of a quadratic function convex upward.

Therefore, the inclination portion 276 of the encapsulating branch 275 is not smoothly connected to a flat portion 278, such that tangent lines to a contour of the encapsulating branch 275 have a rapid gradient change before and behind the lowest point 276′.

According to the configuration described above, a moisture particle present at a point \textcircled{a} is rolled down on the inclination portion 276, and may stop at a point \textcircled{b}. This prevents the moisture particle present at the point \textcircled{a} from being moved to a point \textcircled{c}. Therefore, an amount of moisture particle present at the point \textcircled{c} is decreased.

In addition, as in the above-mentioned exemplary embodiment, the moisture particle present at the point \textcircled{c} has a size smaller than that of the moisture particle present at the point \textcircled{b}. Further, the moisture particle present at the point \textcircled{c} should primarily lift the flat portion 278 and secondarily lift the inclination portion 276.

This action minimizes the possibility that the moisture particle will permeate into the encapsulating body 271 since a size of the moisture particle positioned at the point \textcircled{c} is small, the moisture particle positioned at the point \textcircled{c} does not lift the inclination portion 276 together with the flat portion 278 even though it lifts the flat portion 278, and the moisture particle positioned at the point \textcircled{d} is less exposed to external air, such that force by which the moisture particle is expanded/contracted is weak.

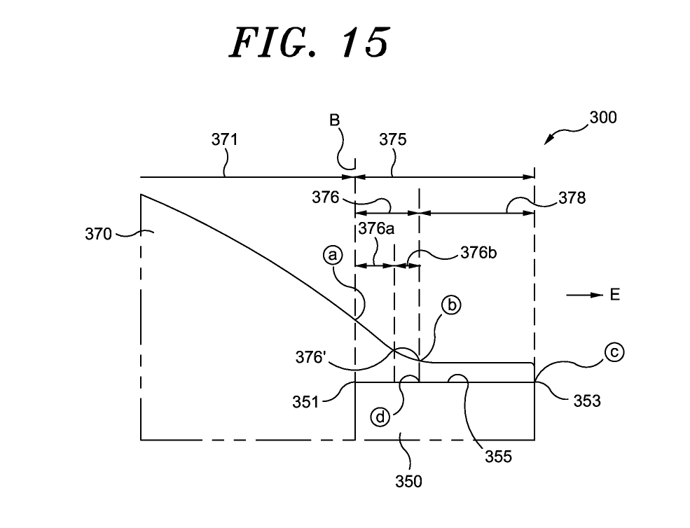

Next, a light emitting device package 300 having still another form will be described with reference to FIG. 15.

FIG. 15 is an enlarged cross-sectional view illustrating configurations of a reflector 350 and an encapsulant 370 of a light emitting device package 300 according to still another exemplary embodiment of the present invention.

Referring to FIG. 15, a reflector 350 and an encapsulant 370 of the light emitting device package 300 are substantially the same as the reflector 150 and the encapsulant 170 described with reference to FIG. 13. However, a flat portion 378 is different from the flat portion 178 described above.

In detail, the flat portion 378 is extended to an outer edge 353 of the reflector 350, such that an encapsulating branch 375 covers the entirety of an upper surface 355 of the reflector 350. Therefore, an exposure area 157 (see FIG. 13) is not formed on the upper surface 355 of the reflector 350.

According to the configuration of the flat portion 378 described above, a size of the flat portion 378 may be maximized within an area corresponding to the reflector 350. This maximizes a permeation path of a moisture particle that is to permeate into the flat portion 378 at a point \textcircled{c} to weaken permeation force of the moisture particle.

Further, a moisture particle rolled down from a point \textcircled{a} may be piled on the flat portion 378 or may drop to the outside of the reflector 350 even though the moisture particle is not piled on the flat portion 378. This decreases an amount of moisture particle that is to permeate into the flat portion 378 at the point \textcircled{c}.

In addition, even though the moisture particle intends to lift the flat portion 378 at the point \textcircled{c}, it will be more difficult to lift the flat portion 378 due to an increase in a weight or a size of the flat portion 378.

Further, since the moisture particle lifting the flat portion 378 and positioned at a point \textcircled{d} is protected by the flat portion 378 having a wider area, a contact between the moisture particle and external air is further restrictive. As a result, force by which the moisture particle positioned at the point \textcircled{d} is expanded/contracted depending a temperature change of the turn on/off of the LED chips 130 (see FIG. 12) is weaker than the force by the above-mentioned exemplary embodiment.

The resin layers are stacked in a two-layer or more, thereby making it possible to economically manufacture a reflector that may perform a function of the reflector, and the light emitting diode module having a narrow light distribution angle or a narrow light distribution angle may be implemented using the reflector without a decrease in light efficiency.

The light emitting diode module as described above is not limited to the configuration and the operation scheme of the above-mentioned exemplary embodiments. The above-mentioned exemplary embodiments may be configured so that various modifications may be made by selective combinations of all or some of the respective exemplary embodiments.

What is claimed is:

1. A light emitting diode module, comprising:
a substrate;
LED chips mounted on an upper surface of the substrate;
a multi-layer reflector formed on the upper surface of the substrate so as to form a cavity in the vicinity of the LED chips and having an annular shape; and
an encapsulant formed of a resin filled in the cavity and containing phosphors,
wherein the multi-layer reflector includes a plurality of resin layers having different inner diameters.

2. The Light emitting diode module of claim 1, wherein the multi-layer reflector includes a first resin layer for the reflector annularly formed on the substrate and a second resin layer for the reflector stacked on the first resin layer for the reflector.

3. The Light emitting diode module of claim 1, wherein the multi-layer reflector includes spiral resin layers for the reflector continuously connected to each other in a spiral shape toward the top.

4. The Light emitting diode module of claim 1, wherein an inner diameter of the multi-layer reflector is gradually decreased toward the top.

5. The Light emitting diode module of claim 1, wherein the resin filled in the cavity and containing the phosphors includes a concave light emitting surface.

6. The Light emitting diode module of claim 1, wherein a height of an upper end of the resin filled in the cavity and containing the phosphors is generally lower than that of an upper end of the multi-layer reflector.

7. The Light emitting diode module of claim 1, wherein an inner side of a cross section of the cavity is any one of one straight line, a combination of straight lines, one curved line, a combination of curved lines, and a combination of lines including a straight line and a curved line.

8. The Light emitting diode module of claim 1, wherein the multi-layer reflector is formed of a resin material in which a translucent resin including a silicon resin or an epoxy resin and a reflection material selected from the group consisting of TiO₂, SiO₂, ZrO₂, PbCO₃, PbO, Al₂O₃, ZnO, and Sb₂O₃ are mixed with each other.

9. The Light emitting diode module of claim 1, wherein the encapsulant has convex shape in a direction that becomes distant from the substrate,
a central axis of the encapsulant coincides with a central axis of the cavity, and
the number of LED chips provided in the cavity is plural.

10. The Light emitting diode module of claim 9, wherein the multi-layer reflector has a height higher than the highest height of the plurality of LED chips and lower than the highest height of the encapsulant.

11. The Light emitting diode module of claim 9, wherein the multi-layer reflector has the same interval with respect to an array central point of the plurality of LED chips in all directions.

12. The Light emitting diode module of claim 9, wherein the encapsulant includes:
an encapsulating body positioned in an area occupied by the cavity; and
an encapsulating branch extended from the encapsulating body so as to cover an upper surface of the multi-layer reflector.

13. The Light emitting diode module of claim 12, wherein the encapsulating branch contains a mixture of the phosphors and silicon.

14. The Light emitting diode module of claim 12, wherein the encapsulating branch includes:
an inclination portion inclined downward in a separation direction that becomes distant from the central axis of the cavity; and
a flat portion flatly extended from the inclination portion in the separation direction.

15. The Light emitting diode module of claim 14, wherein the inclination portion includes:
a first section having a height decrease rate increased in the separation direction; and
a second section extended from the first section and having a height decrease rate converged on zero in the separation direction.

16. The Light emitting diode module of claim 9, wherein the encapsulant includes:
an encapsulating body having a symmetrical shape in relation to the central axis of the cavity; and
an encapsulating branch connected to the encapsulating body so as to enclose the encapsulating body and covering the entirety of an upper surface of the multi-layer reflector.

17. The Light emitting diode module of claim 16, wherein the encapsulating branch includes:
an inclination portion inclined downward in a separation direction that becomes distant from the central axis of the cavity; and
a flat portion flatly extended from the inclination portion to an outer end portion of the multi-layer reflector.

18. The Light emitting diode module of claim 17, wherein the inclination portion includes:
a first section having a height decrease rate increased in the separation direction; and
a second section extended from the first section and having a height decrease rate converged on zero in the separation direction.
